(19) United States
(12) Patent Application Publication
(10) Pub. No.: US 2013/0161670 A1
(43) Pub. Date: Jun. 27, 2013

(54) LIGHT EMITTING DIODE PACKAGES AND METHODS OF MAKING

(71) Applicant: Sheng-Yang Peng, Kaohsiung City (TW)

(72) Inventor: Sheng-Yang Peng, Kaohsiung City (TW)

(21) Appl. No.: 13/336,770

(22) Filed: Dec. 23, 2011

(51) Int. Cl. H01L 33/60; H01L 21/48; H01L 33/62

(52) U.S. Cl. 257/98; 257/99; 427/58; 257/E33.066; 257/E33.06

(57) ABSTRACT

Light emitting, diode (LED) packages and processes with improved heat dissipation. In certain embodiments, only metal solder resides in the space between the leadframe and the circuit board, providing good heat conduction from the LED chip to the circuit board. In certain embodiments, sidewalls of the leadframe are tilted to provide improved light emission.

### TECHNICAL FIELD

The present embodiments relate to semiconductor device packages, in particular light emitting diode (LED) packages and methods of making the same.

### BACKGROUND

LED dies have been widely applied in illumination devices because of their brightness and light emitting efficiency. However, LED dies still encounter heat dissipation problems, which may cause the light emission and color of the LED dies to degrade. One solution for increased heat dissipation is to mount LED dies on ceramic substrates. But ceramic substrates are expensive, and significantly raise the cost of the LED packages. Thus, more cost-effective LED packages with good heat dissipation efficiency would be beneficial.

### SUMMARY

One of the present embodiments comprises a semiconductor device package. The package comprises a leadframe having a metal substrate, a first metal layer on an upper surface of the metal substrate, and a second metal layer on a lower surface of the metal substrate. The leadframe defines a cavity including a cavity bottom portion. The package further comprises at least one light emitting diode (LED) chip disposed on and electrically connected to the first metal layer of the cavity bottom portion. The package further comprises an encapsulant disposed on the first metal layer and encapsulating the at least one LED chip and at least a portion of the first metal layer. The second metal layer is entirely exposed.

Another of the present embodiments comprises a semiconductor device package. The package comprises a leadframe defining a cavity and having opposing inner and outer surfaces. The package further comprises at least one light emitting diode (LED) chip disposed on and electrically connected to the inner surface of the leadframe. The package further comprises an encapsulant encapsulating the at least one LED chip and at least partially covering the inner surface of the leadframe. The outer surface of the leadframe is uncovered by any encapsulant.

Another of the present embodiments comprises a method of making a leadframe for a semiconductor device package. The method comprises stamping a planar metal substrate to produce a plurality of concave substructures, each substructure defining a cavity with a flange extending from a periphery thereof. The method further comprises forming a first photoresist layer on an upper surface of the metal substrate, and a second photoresist layer on a lower surface of the metal substrate. The method further comprises forming a first photoresist pattern in the first photoresist layer, and a second photoresist pattern in the second photoresist layer. The method further comprises using the first and second photoresist patterns as masks and forming a first metal layer on the upper surface of the metal substrate in areas not covered by the first photoresist pattern, and a second metal layer on the lower surface of the metal substrate in areas not covered by the second photoresist pattern. The method further comprises removing the first and second photoresist patterns to create channels in the first and second metal layers.

### BRIEF DESCRIPTION OF THE DRAWINGS

FIG. 1A is a schematic cross-sectional view of an LED package structure according to one of the present embodiments;

FIG. 1B is a schematic top plan view of he LED package structure of FIG. 1A;

FIG. 2 is a schematic cross-sectional view of an LED package structure according to another of the present embodiments;

FIGS. 3A-3F illustrate a method of making a leadframe unit structure according to one of the present embodiments;

FIGS. 4A-4I illustrate a method of making a leadframe unit structure according to another of the present embodiments;

FIGS. 5A-5F illustrate a method of making a leadframe unit structure according to another of the present embodiments;

FIG. 5F′ is a schematic top plan view of the structure of FIG. 5F; and

FIGS. 6A-6F are schematic top views of various LED package structures according to the present embodiments.

Common reference numerals are used throughout the drawings and the detailed description to indicate the same elements. The present invention will be more apparent from the following detailed description taken in conjunction with the accompanying drawings.

### DETAILED DESCRIPTION

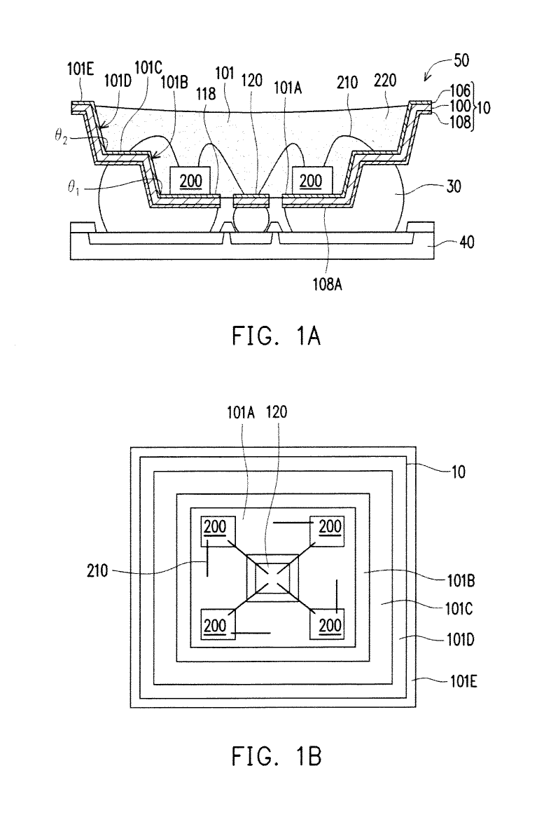

Referring, to FIGS. 1A and 1B, one of the present embodiments of a semiconductor device package 50 is illustrated. The package 50 includes a leadframe 10, one or more LED chips 200 secured to the leadframe 10, wires 210 electrically connecting the LED chips 200 to the leadframe 10, and encapsulant 220 surrounding the LED chips 200 and the wires 210. The semiconductor device package 50 is physically and electrically connected to a circuit board 40 through solder 30. The circuit board 40, which may be a printed circuit board (PCB) in one embodiment, is external to the semiconductor device package 50.

With reference to FIG. 1A, the leadframe 10 includes a metal substrate or core 100, a first or upper metal layer 106, and a second or lower metal layer 108 disposed on opposite surfaces of the metal substrate 100. The metal layers 106, 108 may be joined with the metal core 100 by plating, for example, or any other process. The leadframe 10 further includes a cavity 101 having a cavity bottom 101A, first inclined sidewalls 101B extending from the cavity bottom 101A, substantially horizontal wire bonding areas 101C extending from the first inclined sidewalls 101B, second inclined sidewalls 101D extending from the bonding areas 101C, and flange portions 101E extending from the second inclined sidewalls 101D. The first inclined sidewalls 101B, the substantially horizontal wire bonding areas 101C, and the second inclined sidewalls 101D may be referred to collectively as “sidewalls” of the leadframe 10.

The various inclined sidewalls, bonding areas and flanges circumscribe the leadframe 10 in a contiguous manner, as illustrated in FIG. 1B, and form successive steps or levels, as illustrated in FIG. 1A. While three steps are shown, fewer or more steps may be provided to suit any given application. The steps are arranged in an outwardly expanding fashion from the cavity bottom 101A upward. The leadframe 10 thus defines a concave pyramidal or conical shape having an upper diameter, at the height of the flange portions 101E, greater than a lower diameter, at the height of the cavity bottom 101A.

The cavity bottom 101A includes die pads 118 surrounding a central pad 120. The die pads 118 are physically and electrically isolated from the central pad 120. The chips 200 are attached to the die pads 118 and wire bonded to the central pad 120 and to the wire bonding areas 101C through the wires 210. The central pad 120 serves as an electrical common, which may be power or ground, for example.

The chips 200 may be physically and/or electrically connected within the cavity 101 through other techniques. For example, the chips 200 may be down bonded to the die pads 118. Alternatively to wire bonding, the chips 200 may be inverted so that the active surface of each faces down, and flip chip bonded to the leadframe 10.

With continued reference to FIG. 1A, the encapsulant 220 fills, or partially fills, the cavity and encapsulates the chips 200 and the wires 210. The encapsulant 220 may be a silicone-based or epoxy resin, for example, or any other material. The encapsulant 220 may further include conversion substance particles, such as phosphor particles, so as to produce a desired light color. In another embodiment, a phosphor layer (not shown) may be located between the chips 200 and the encapsulant 220. The phosphor layer may cover the upper surfaces and/or the side surfaces of the chips 200. In addition, the phosphor layer may be disposed in a lower portion of the cavity defined by the first inclined walls 101B, while the encapsulant 220 is disposed in an upper portion of the cavity defined by the second inclined walls 101D.

The inclined side walls 101B, 101D at least partially surround the mounting region and the chips 200. The inclined side walls 101B, 101D advantageously reflect light emitted from the chips 200, thereby increasing the light output of the semiconductor device package 50. In one embodiment, the metal layer 106 may be a highly reflective metal layer made of e.g., silver (Ag), Platinum (Pt), tin (Sn), or any other material, for further increasing the light output. Advantageously, there is no material above the flange portions 101E to receive light emitted from the chips 200. There is, for example, no molded material in this area. A greater proportion of the light emitted from the chips 200 is thus reflected off the highly reflective surfaces of the inclined side walls 101B, 101D, increasing the light emission from the semiconductor device package 50.

In the embodiments shown in FIGS. 1, 2, 5G, 6C & 6F, the leadframe is divided by the opening S into a central portion surrounded by additional portions, which provides good mechanical stability against problems arising from mismatched coefficients of thermal expansion (CTE) between the encapsulant 220 and the leadframe 10′.

The light output may be further enhanced by selecting an angle, or angles Θ₁, Θ₂ at which the inclined side walls 101B, 101D meet the cavity bottom 101A and the horizontal portions 101C. In the illustrated embodiment, the angles Θ₁, Θ₂ are substantially equal. However, in alternative embodiments the angles Θ₁, Θ₂ may not be equal. It has been found through simulations that angles within the range 140°-170° provide enhanced light emitting performance. However, in alternative embodiments the angles Θ₁, Θ₂ may be approximately 90°, such that the side walls 101B, 101D are substantially vertical.

With continued reference to FIG. 1A, the semiconductor device package 50 is physically and electrically connected to a circuit board 40 through solder 30. However, prior to being connected to the circuit board 40, a lower surface 108A of the lower metal layer 108 is completely exposed in all regions of the leadframe 10, including the central pad 120, the die pads 118, the first inclined sidewalls 101B, the wire bonding areas 101C, the second inclined sidewalls 101D, and the flange portions 101E. Thus, after connection to the circuit board 40, the primary heat transfer path for cooling the chips 200 is through the solder 30 to the circuit board 40. Solder, being a metal, has good thermal conduction properties. There is, for example, no polymeric material between the chips 200 and the circuit board 40, which would decrease the heat conductivity between the chips 200 and the circuit board 40. The present embodiments thus provide excellent thermal transfer from the chips 200 to the circuit board 40 to keep the operating temperature of the chips 200 low, thereby increasing their performance efficiency and decreasing the likelihood that their performance will degrade due to overheating. The present embodiments also avoid using ceramic substrates, which would undesirably increase the cost of the semiconductor device packaging.

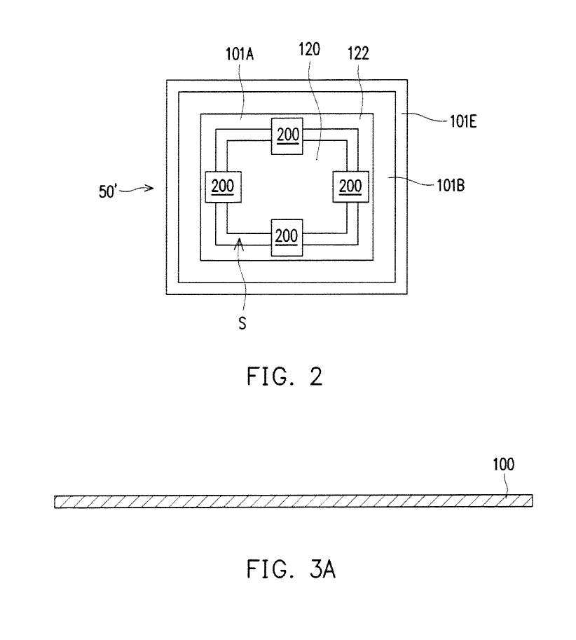

FIG. 2 illustrates an alternative semiconductor device package 50′. The package 50′ includes a leadframe 10, and one or more LED chips 200 secured to the leadframe 10′. However, unlike the embodiment of FIG. 1, which includes wires 210 electrically connecting the LED chips 200 to the leadframe 10, the LED chips 200 in FIG. 2 are mounted using a flip-chip technique. Further, the leadframe 10′ includes a cavity bottom 101A, first inclined sidewalls 101B extending from the cavity bottom 101A, and flange portions 101E extending from the first inclined sidewalls 101B. The leadframe 10′ does not include wire bonding areas 101C or second inclined sidewalls 101D. A gap S separates the cavity bottom 101A into first and second portions 120, 122, with the gap S circumscribing the first portion 120 and the second portion 122 circumscribing the gap S. The LED chips 200 are arranged on the leadframe 10′ such that each one straddles the gap. This configuration, which is also embodied in some embodiments below, provides good mechanical stability against problems arising from mismatched coefficients of thermal expansion (CTE) between the encapsulant 220 and the leadframe 10′.

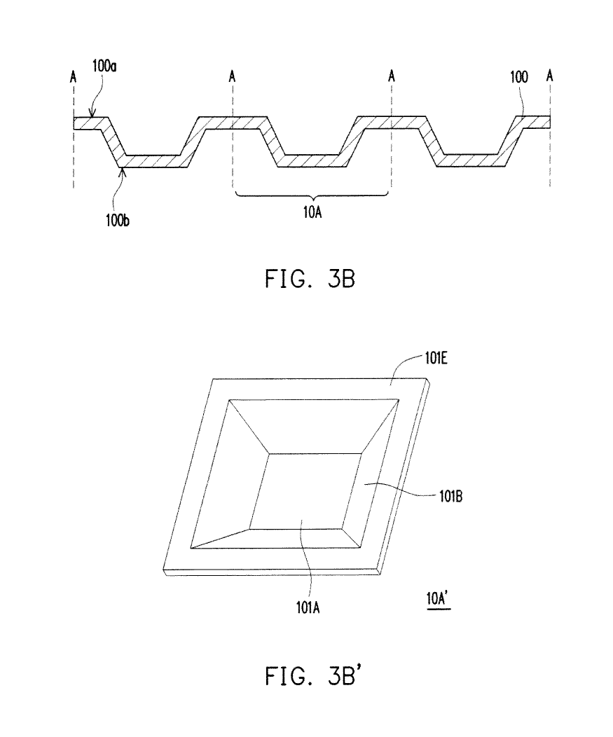

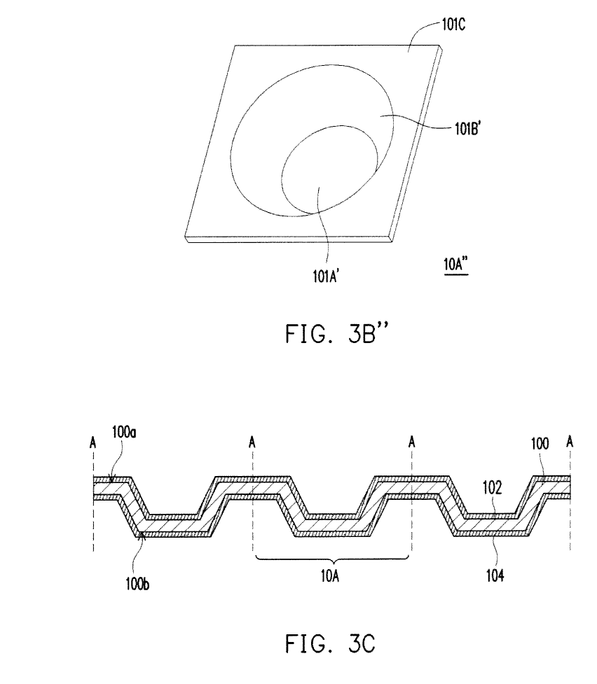

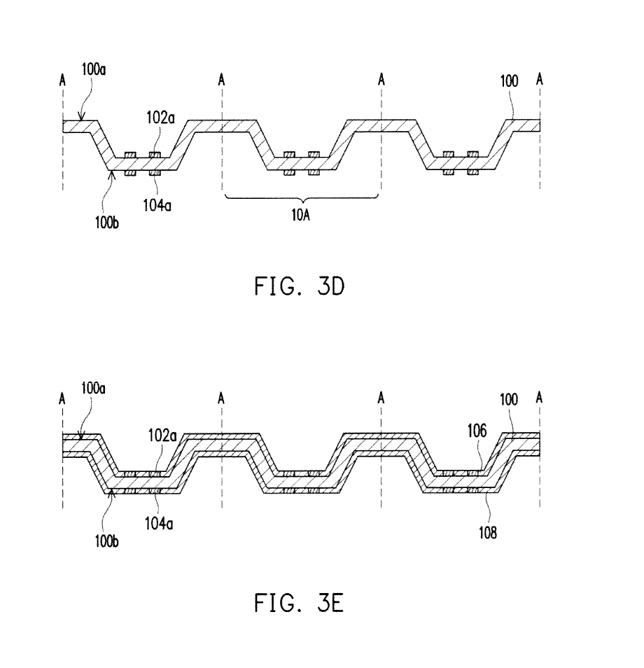

FIGS. 3A-3F illustrate steps in a method for making LED semiconductor device packages according to the present embodiments. FIG. 3A illustrates a metal substrate 100 in the shape of a flat sheet or strip. The metal substrate 100 may be, for example, a copper foil having a thickness of about 100-150 microns, or any other suitable material.

Referring to FIG. 3B, a stamping process shapes the metal substrate or core 100 into a plurality of concave substructures 10A. The dotted separation lines A-A illustrate one substructure 10A. The substructures 10A may be shaped like a dish or plate in a round or square shape. FIG. 3B″ illustrates one example substructure 10A″ shaped as a flanged dish. The dish includes a square cavity bottom 101A having inclined sidewalls 101B extending therefrom, and a flange portion 101E extending from the inclined sidewalls 101B. FIG. 3B′ illustrates another example substructure 10A″, also shaped as a flanged dish, but having a round cavity bottom 101A and one continuous inclined sidewall 101B.

Referring to FIG. 3C, a first photoresist layer 102 is formed on the upper surface 100a of the metal substrate 100, and a second photoresist layer 104 is formed on the lower surface 100b of the metal substrate 100. The first and second photoresist layers 102, 104 may be formed by spray coating or dip coating, for example, or by any other technique. A photoresist layer formed by spray coating is more likely to have better uniformity and conformity. However, dip coating may be used to form the photoresist layers 102, 104 on both surfaces 100a, 100b simultaneously. The thickness of the first and second photoresist layers 102, 104 may be 6 microns, for example, or any other thickness.

Referring to FIG. 3D, a first photoresist pattern 102a is formed on the upper surface 100a, and a second photoresist pattern 104a is formed on the lower surface 100b of the metal substrate 100. The patterns may be formed by etching, for example, or any other process. In the illustrated embodiment, all of the photoresist patterns 102a, 104a are the same, but in alternative embodiments the first photoresist pattern 102a may differ from the second photoresist pattern 104a.

Referring to FIG. 3E, using the first and second photoresist patterns 102a, 104a as masks, a first metal layer 106 is formed on the upper surface 100a that is not covered by the first photoresist pattern 102a, and a second metal layer 108 is formed on the lower surface 100b that is not covered by the second photoresist pattern 104a. Either of both of the first metal layer 106 and the second metal layer 108 may be a single layer or a multiple metal laminated layer, such as nickel/gold (Ni/Au) laminated layer. The layers 106, 108 may be made by plating, for example, or any other process.

Referring to FIG. 3F, the first and second photoresist patterns 102a, 104a are removed to create channels 105, 107 in the first and second metal layers 106, 108. While it appears that two channels 105, 107 are provided in each metal layer 106, 108, the two illustrated gaps in each metal layer 106, 108 may actually be different portions of the same slit. The apparatus of FIG. 3F comprises a leadframe strip 20 including a plurality of leadframe units 10A. The leadframe strip 20 will be assembled with chips and other electronic devices in subsequent processes. After assembly, the leadframe strip 20 will be cut along the separation lines A to separate the leadframe units 10A.

Advantageously, the method of FIGS. 3A-3F is a simple process, having relatively few steps, for producing leadframes. This method thus provides advantages such as low cost and quick turnaround.

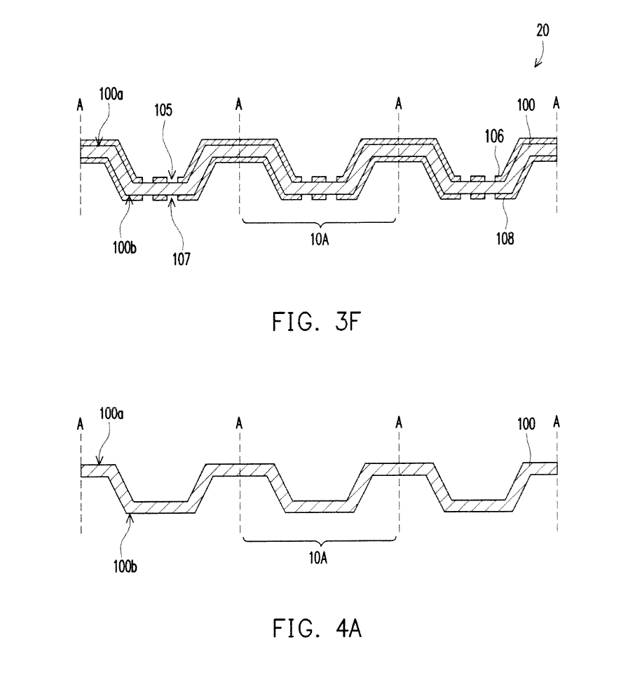

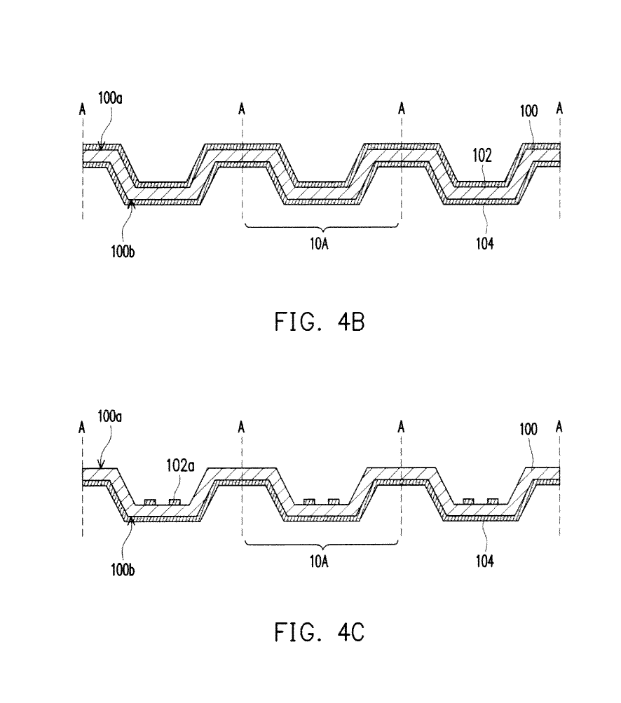

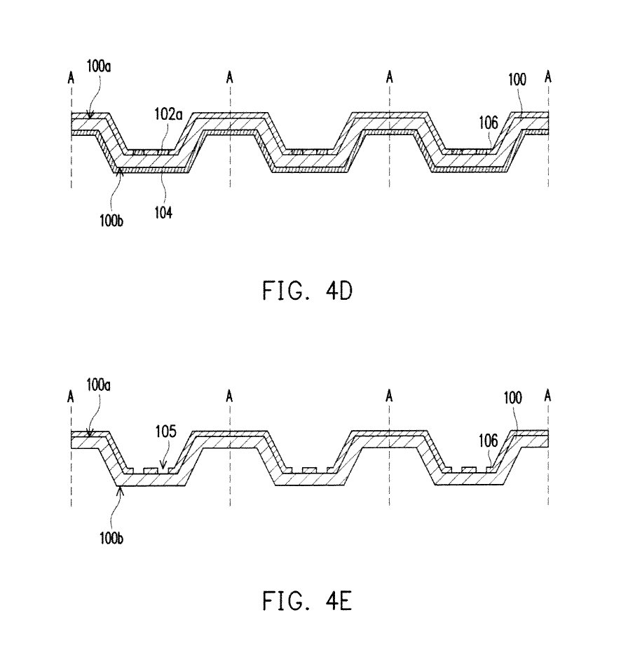

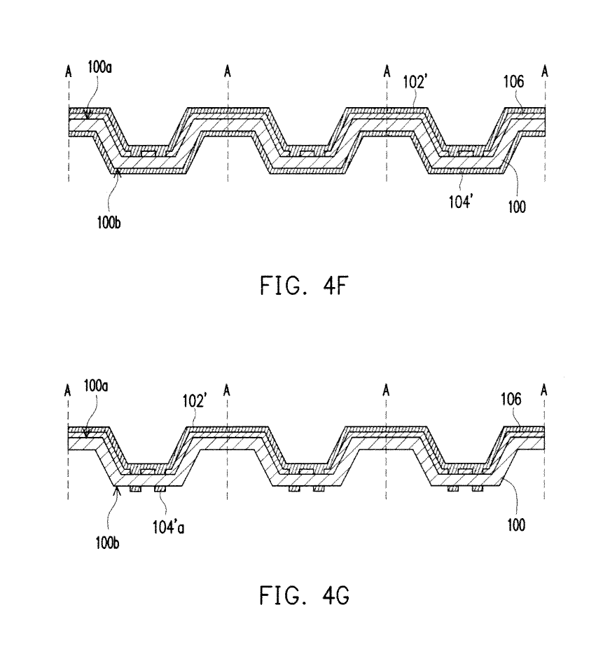

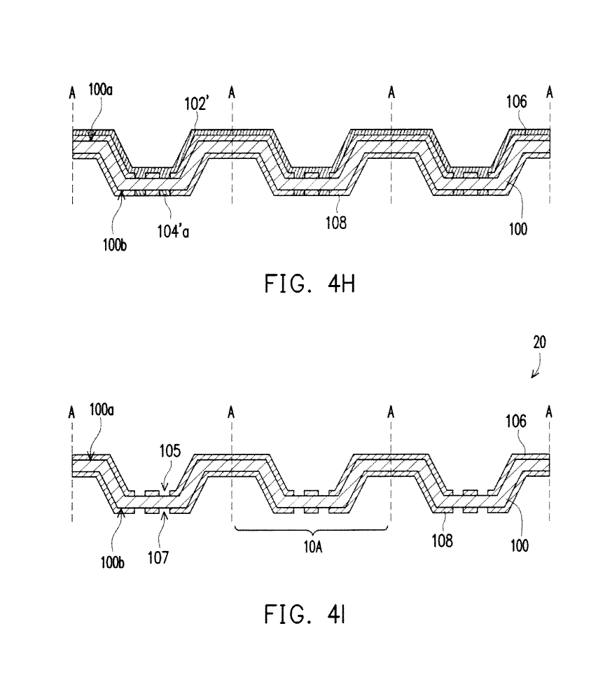

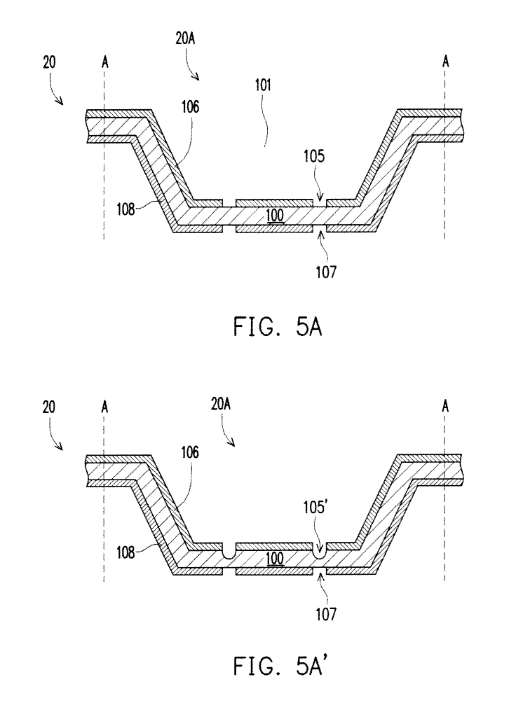

FIGS. 4A-4I illustrate steps in another method for making LED semiconductor device packages according to the present embodiments. Some aspects of the embodiment of FIGS. 4A-4I are similar to those of the embodiment of FIGS. 3A-3F. Accordingly, discussion of those aspects will be omitted for FIGS. 4A-4I.

Referring to FIG. 4A, a stamping process shapes the metal substrate or core 100 into a plurality of concave substructures 10A. Referring to FIG. 4B, a first photoresist layer 102 is formed on the upper surface 100a of the metal substrate 100, and a second photoresist layer 104 is formed on the lower surface 100b of the metal substrate 100.

Referring to FIG. 4C, a first photoresist pattern 102a is formed on the upper surface 100a of the metal substrate 100. In contrast to the embodiment of FIGS. 3A-3F, no second photoresist pattern is formed on the lower surface 100b of the metal substrate 100 at this time.

Referring to FIG. 4D, using the first photoresist pattern 102a as a mask, a first metal layer 106 is formed on the upper surface 100a of the metal substrate 100 that is not covered by the first photoresist pattern 102a. Referring to FIG. 4E, the first photoresist pattern 102a is removed, so that at least one slit 105 is formed in the first metal layer 106, and the second photoresist layer 104 is removed from the lower surface 100b of the metal substrate 100.

Referring to FIG. 4F, a third photoresist layer 102′ is formed on the upper surface 100a of the metal substrate 100 and on the first metal layer 106. A fourth photoresist layer 104′ is formed on the lower surface 100b of the metal substrate 100. Referring to FIG. 4G, a second photoresist pattern 104 is formed on the lower surface 100b of the metal substrate 100.

Referring to FIG. 4H, using the second photoresist pattern 104′a as a mask, a second metal layer 108 is formed on the lower surface 100b that is not covered by the second photoresist pattern 104′a. Referring to the FIG. 4I, the third photoresist layer 102′ and the second photoresist pattern 104′a are removed to create channels 105, 107 in the first and second metal layers 106 and 108. The apparatus of FIG. 4I comprises a leadframe strip 20 including a plurality of leadframe units 10A. The leadframe strip 20 will be assembled with chips and other electronic devices in subsequent processes. After assembly, the leadframe strip 20 will be cut along the separation lines A to separate the leadframe units 10A.

In the foregoing embodiment, the process steps for patterning and/or forming the metal layers on two opposite surfaces of the leadframe are performed in sequential steps. This method thus advantageously allows the metal layers on two opposite surfaces of the leadframe to be of different materials or thickness. For example, the first metal layer 116 can be a highly reflective silver layer while the second metal layer 108 can be a nickel and gold laminated layer (Ni/Au layer). This method thus offers greater design flexibility for the end products.

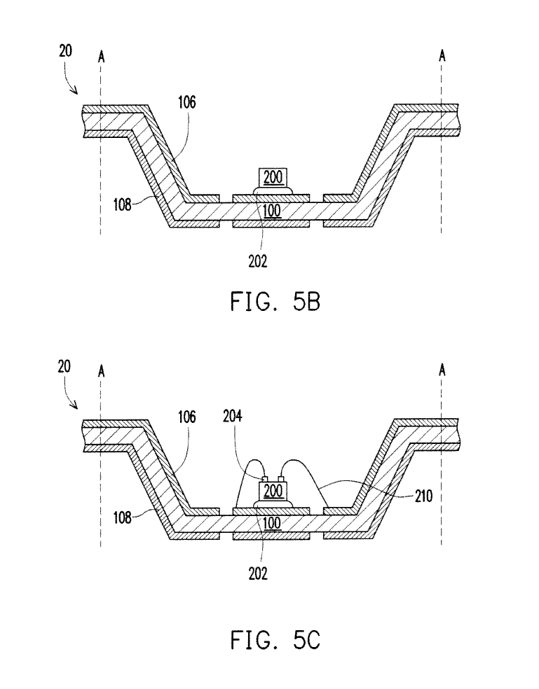

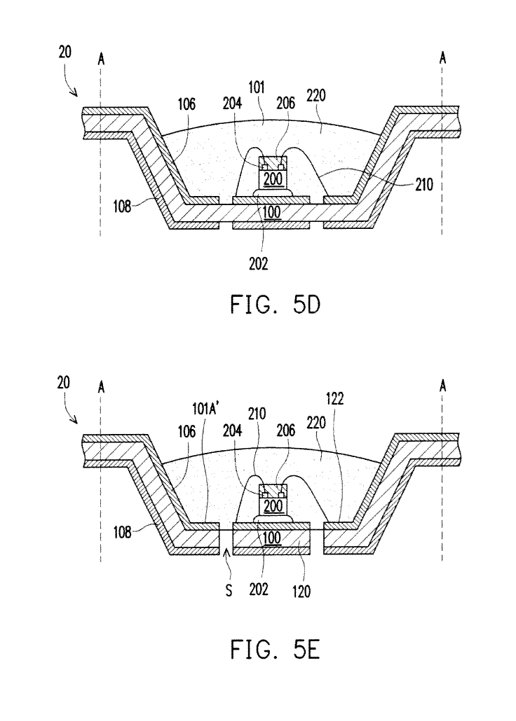

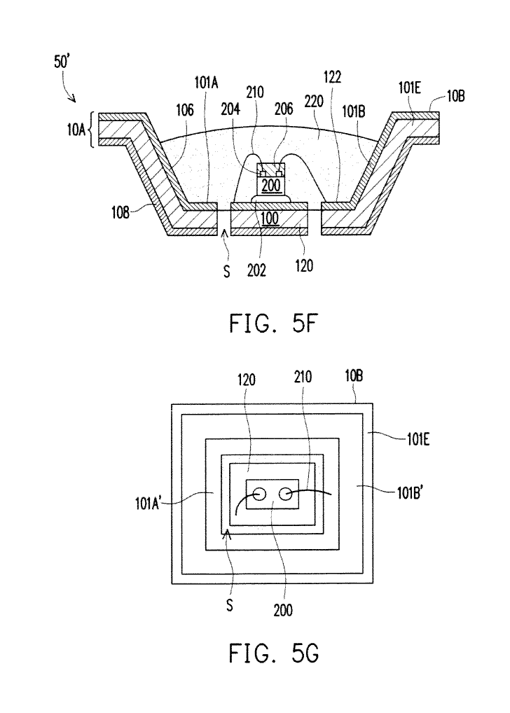

FIGS. 5A-5F illustrate steps in another method for making LED semiconductor device packages according to the present embodiments. Referring to FIG. 5A, a leadframe strip 20 includes the metal substrate 100, the first metal layer 106, the second metal layer 108, and channels 105, 107 in the metal layers 106, 108. Only one leadframe unit 20A is shown in FIG. 5A, as indicated by the dotted lines A-A. The leadframe unit 20A includes the cavity 101. Referring to FIG. 5A′, in an alternative embodiment the first metal layer 106 may be used as an etching mask to perform a half-etching process to the slit 105, so that the depth of the slit 105′ is increased. This step can enhance the adhesion between the leadframe and the subsequently filled encapsulant.

Referring to FIG. 5B, at least one chip 200 is disposed on the first metal layer 106 and on the central portion within the slit 105. The chip 200 may be fixed to the first metal layer 106 through an adhesive layer 202, for example, or using any other technique. The chip 200 may be, for example, an LED chip, such as a high power LED chip. Referring to FIG. 5C, a plurality of wires 210 are formed between contact pads 204 of the chip 200 and the first metal layer 106 to electrically connect the chip 200 to the first metal layer 106.

Referring to FIG. 5D, a phosphor layer 206 is formed over the chip 200. The phosphor layer 206 may cover the upper surface of the chip 200 only, or also cover the sides of the chip 200. Subsequently, the encapsulant 220 is formed in the cavity 101 to cover the chip 200 and the wires 210. The encapsulant 220 may partially fill or completely fill the cavity 101. The material of the encapsulant 220 may he any transparent encapsulant material, such as silicone-based or epoxy resins. If the chip 200 is, for example, a high power LED chip, a silicon based molding material is preferred for its resistance to yellowing. If the chip 200 is a general LED chip, an epoxy based molding material is harder and provides better adhesion.

Referring to FIG. 5E, using the second metal layer 108 as an etching mask, the metal substrate 100 is etched from the slit 107 (from the lower side) until the encapsulant 220 is exposed, so as to form the opening S. The opening S penetrates completely through the metal substrate 100 such that the cavity bottom 101A includes the central pad 120, which is electrically isolated from a remainder or peripheral portion 122 of the cavity bottom 101A. While the central pad 120 and the peripheral portion 122 are electrically isolated from each other, they are physically connected to each other through the encapsulant 220.

Referring to FIG. 5F and 5G, a singulation step is performed to cut the leadframe strip 20 along the separation lines A to form the individual package structures 50. Each package structure 50 includes a single leadframe 10B. The package structure 50′ is similar to the package structure 50 of FIGS. 1A and 1B, but the package structure 50 includes only a single chip 200 and fewer steps in the sidewalls 101B. In a subsequent step, the semiconductor device package 50′ is physically and electrically connected to a circuit board (not shown). However, with reference to FIG. 5F, prior to being connected to the circuit board, a lower surface 108A of the lower metal layer 108 is completely exposed in all regions of the leadframe 10B, including the central pad 120, the peripheral portion 122, the first inclined sidewalls 101B, and the flange portions 101E.

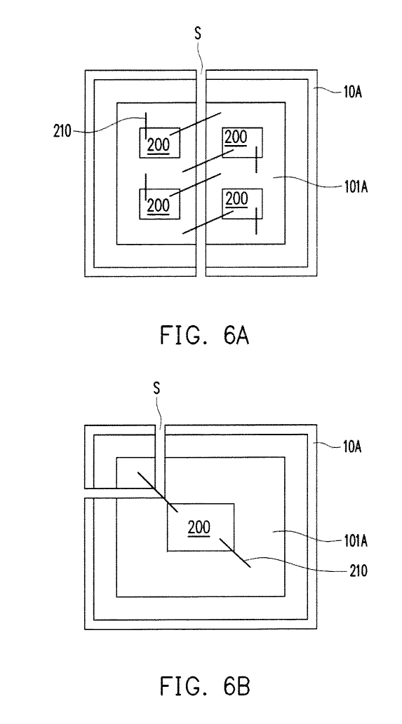

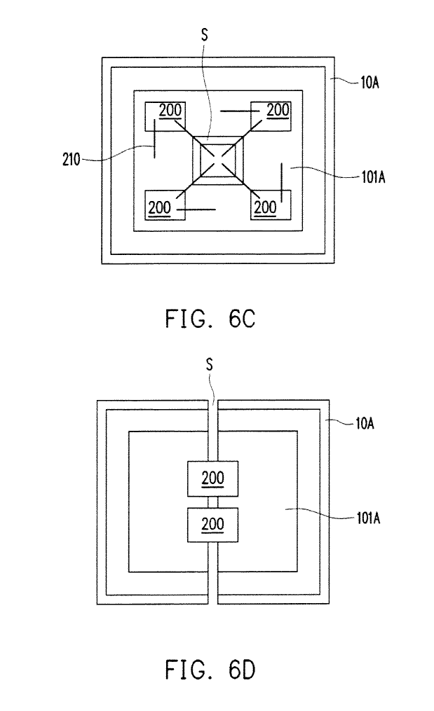

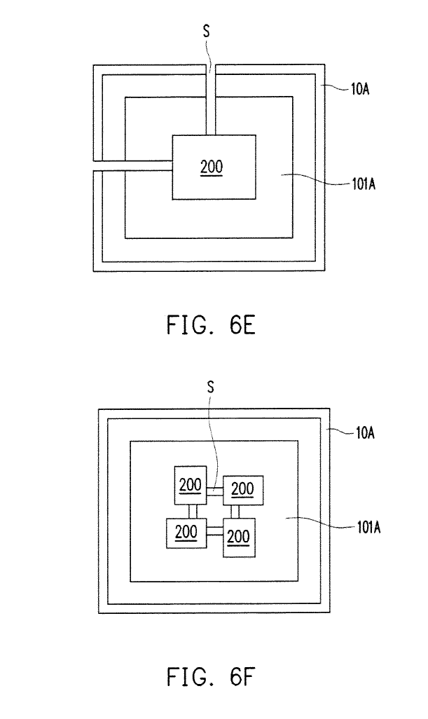

FIGS. 6A-6F illustrate several LED package structures having different configurations for the opening S. The encapsulant is omitted for clarity. Referring to Figures 6A and 6D, the opening S may be a linear trench. Referring to FIGS. 6B and 6E, the opening S may be an L-shaped trench. Referring to FIGS. 6C and 6F, the opening S may be a square loop trench located within the cavity bottom 101A. Referring to FIGS. 6A-6C, the chip 200 is electrically connected to the leadframe unit with wires 210. Referring to FIGS. 6D-6F, the chip 200 is electrically connected to the leadframe unit through flip chip technology, which may include solder bumps.

While the invention has been described and illustrated with reference to specific embodiments thereof these descriptions and illustrations do not limit the invention. It should be understood by those skilled in the art that various changes may be made and equivalents may be substituted without departing from the true spirit and scope of the invention as defined by the appended claims. The illustrations may not be necessarily being drawn to scale. There may be distinctions between the artistic renditions in the present disclosure and the actual apparatus due to manufacturing processes and tolerances. There may be other embodiments of the present invention which are not specifically illustrated. The specification and the drawings are to be regarded as illustrative rather than restrictive. Modifications may be made to adapt a particular situation, material, composition of matter, method, or process to the objective, spirit and scope of the invention. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A semiconductor package, comprising:
a leadframe having a metal substrate, a first metal layer on an upper surface of the metal substrate, and a second metal layer on a lower surface of the metal substrate, wherein the leadframe defines a cavity including a cavity bottom portion:
at least one light emitting diode (LED) chip disposed on and electrically connected to the first metal layer of the cavity bottom portion; and
an encapsulant disposed on the first metal layer and encapsulating the at least one LED chip and at least a portion of the first metal layer, wherein the second metal layer is entirely exposed.

2. The semiconductor package of claim 1, wherein the cavity bottom portion has at least one through opening dividing the cavity bottom portion into at least two portions that are electrically isolated from one another.

3. The semiconductor package of claim 2, wherein the through opening divides the cavity bottom portion of the leadframe into a central portion surrounded by the through opening and a peripheral portion outside of the through opening.

4. The semiconductor package of claim 1, further comprising a stepped cavity sidewall portion.

5. The semiconductor package of claim 1, wherein the cavity further defines a first cavity sidewall portion extending at a first angle from the cavity bottom portion, a substantially horizontal portion extending from the first cavity sidewall portion, and a second cavity sidewall portion extending at a second angle from the substantially horizontal portion.

6. The semiconductor package of claim 4, wherein the first angle is in a range of 140°-170°.

7. The semiconductor package of claim 4, wherein the second angle is in a range of 140°-170°.

8. The semiconductor package of claim 4, further comprising a flange portion extending from the second cavity sidewall portion.

9. A semiconductor package, comprising:
a leadframe defining a cavity and having opposing inner and outer surfaces;
at least one light emitting diode (LED) chip disposed on and electrically connected to the inner surface of the leadframe;
means for optimizing optics of the LED: and
an encapsulant encapsulating the at least one LED chip and at least partially covering the inner surface of the leadframe, wherein the outer surface of the leadframe is uncovered by any encapsulant.

10. The semiconductor package of claim 9, further comprising a through opening dividing a cavity bottom portion into at least a central portion enclosed by the through opening and a peripheral portion outside of the through opening.

11. The semiconductor package of claim 9, wherein the means for optimizing optics of the LED comprises a stepped cavity sidewall portion.

12. The semiconductor package of claim 9, wherein the means for optimizing optics of the LED comprises inclined cavity side walls.

13. The semiconductor package of claim 12, wherein the cavity side walls are stepped.

14. The semiconductor package of claim 9, wherein the means for optimizing optics of the LED comprises a cavity sidewall portion, and an upper extent of the encapsulant is recessed below an upper extent of the cavity sidewall portion.

15. The semiconductor package of claim 9, wherein the means for optimizing optics of the LED comprises a cavity sidewall portion including a highly reflective metal layer.

16. A method of making a leadframe for a semiconductor package, the method comprising:
stamping a planar metal substrate to produce a plurality of concave substructures, each substructure defining a cavity with a flange extending from a periphery thereof:
forming a first photoresist layer on an upper surface of the metal substrate, and a second photoresist layer on a lower surface of the metal substrate;
forming a first photoresist pattern in the first photoresist layer, and a second photoresist pattern in the second photoresist layer;
using the first and second photoresist patterns as masks, forming a first metal layer on the upper surface of the metal substrate in areas not covered by the first photoresist pattern, and a second metal layer on the lower surface of the metal substrate in areas not covered by the second photoresist pattern; and
removing the first and second photoresist patterns to create channels in the first and second metal layers.

17. The method of claim 16, wherein the first and second photoresist layers are formed by spray coating or dip coating.

18. The method of claim 16, wherein the first and second photoresist patterns are formed by etching.

19. The method of claim 16, wherein the first and second metal layers are formed by plating.

20. The method of claim 16, wherein the channels in the first metal layer correspond in position to the channels in the second metal layer.
